(19) United States
(12) Patent Application Publication
(10) Pub. No.: US 2011/0174358 A1
(43) Pub. Date: Jul. 21, 2011

(54) FRAME STRUCTURE OF CONCENTRATOR TYPE SOLAR CELL MODULE

(75) Inventors: HWA-YUH SHIN, Taoyuan (TW); Hung-Sheng Chiu, Taoyuan (TW); Chun-Yi Chen, Taoyuan (TW); Hung-Zen Kuo, Taoyuan (TW); Ying-Ru Chen, Taoyuan (TW); Yi-Ya Huang, Taoyuan (TW); Cherng-Tsong Kuo, Taoyuan (TW)

(73) Assignee: Institute of Nuclear Energy Research, Atomic Energy Council, Executive Yuan, Longtan Township (TW)

(21) Appl. No.: 12/771,823

(22) Filed: Apr. 30, 2010

(30) Foreign Application Priority Data
Jan. 15, 2010 (TW) 099101074

(51) Int. Cl. H01L 31/052

(52) U.S. Cl. 136/246

(57) ABSTRACT

A frame structure of a concentrator type solar cell module, with its carrier portion and connection and fixing portion of a frame edge designed into a vertical and stack-up arrangement, thus reducing significantly a thickness of the frame edge, such that upon carrying a concentrator lens array, the proportion of light receiving area is increased, hereby raising the photo-electrical conversion efficiency of the concentrator type solar cell module. Therefore, in this way, in a condition of maintaining a same load mechanical strength, the ineffective light receiving area can be reduced significantly, while raising the photo-electrical conversion efficiency of the solar cell module.

### BACKGROUND OF THE INVENTION

1. Field of the Invention

The present invention relates to a concentrator type solar cell module, and in particular to a frame structure of a concentrator type solar cell module.

2. The Prior Arts

Presently, among the energy regeneration systems, the high concentrated photovoltaic (HCPV) electricity generation system has excellent potential for further development, due to its various advantages of material saving, reduced cost and high efficiency in generating electricity. As such, it is generally considered as ideal to be used in building solar energy power plant, thus it has a promising future in the solar energy industry.

Refer to FIG. 1 for a schematic diagram of a concentrator type solar cell module according to the prior art. As shown in FIG. 1, the concentrator type solar cell module includes: an upper frame 12; a lower frame 13, four angle columns 15; four sideboards 14; a concentrator lens 11, carried and supported on the upper frame 12; and a solar cell unit and a heat dissipation module constituting the solar cell components are disposed in an inner space formed and surrounded by the upper frame 12, the lower frame 13, the angle columns 15, and the sideboards 14. The concentrator lens 11 is capable of concentrating and focusing the sunlight onto solar cell unit in the inner space, thus generating electricity for outputting it to the various equipment as required. Also, a heat dissipation module is provided to dissipate heat generated in the process. As such, through this kind of arrangement mentioned above, the number of solar cell units utilized can be reduced, hereby reducing the cost of equipment required.

Moreover, refer to FIG. 2 for a schematic diagram of a frame structure of a concentrator type solar cell module according to the prior art at the same time. As shown in FIG. 2, in this frame structure, on the left side of the upper frame 12 is provided with a connection and fixing portion formed by a positioning slot 121 and fixing slot 122, used for the sideboard 14 to be engaged and positioned into the positioning slots 121 through a positioning portion 141 extended and bent on a side of the sideboard, and it is screwed and fixed into the fixing slot 122 by means of a screw 16, such that the sideboard 14 is fixed and pressed tightly to the upper frame 12; and on the right side of the upper frame 12 is a step-shaped carrier portion 123, used for the placement of the concentrator lens 11. Since the connection and fixing portion and the carrier portion 123 are placed in a parallel arrangement, such that on the frame edges of the upper frame 12, there are quite a few regions that could have no actual functions. In other words, only the sunlight passing through the concentrator lens 11 and entering into the solar cell unit can be used for generating electricity, therefore, the frame edge region seems to be quite a waste, as such, it not only occupies additional space, but it also reduce the overall photo-electric conversion efficiency of the solar cell unit.

Therefore, presently, the performance and effectiveness of this kind of design is not quite satisfactory.

In view of the problems and shortcomings of the prior art, the present invention provides a frame structure of a concentrator type solar cell module, so as to solve the afore-mentioned problems of the prior art.

### SUMMARY OF THE INVENTION

A major objective of the present invention is to provide a frame structure of a concentrator type solar cell module, wherein, frame edges are designed into a vertical and stack-up arrangement, so as to reduce the area occupied by the frame edges, such that it can not only increase the proportion of light receiving area, but it can also increase the photo-electric conversion efficiency of the solar cell module, hereby resolving the drawbacks and shortcomings of the prior art.

In order to achieve the above-mentioned objective, the present invention provides a frame structure of a concentrator type solar cell module, it basically is a rectangular body formed by four frame edges, and a sideboard is connected and fixed to each frame edge and is used for carrying the concentrator lens array; each frame edge is provided with a carrier portion and a connection and fixing portion, the connection and fixing portion is used to connect and fix a sideboard, and the carrier portion is used to place and carry the concentrator lens array. Wherein, the carrier portion and the connection and fixing portion are designed into a vertical and stack-up arrangement, so as to reduce the thickness of frame edge and the ineffective light receiving area.

Since the thickness of frame edge is reduced, therefore, as viewed from the top, the proportion of area occupied by a concentrator lens array is increased, such that the light receiving area is increased, hereby raising the photo-electric conversion efficiency of a solar cell module.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram of a concentrator type solar cell module according to the prior art;

FIG. 2 is a schematic diagram of a frame structure of a concentrator type solar cell module according to the prior art;

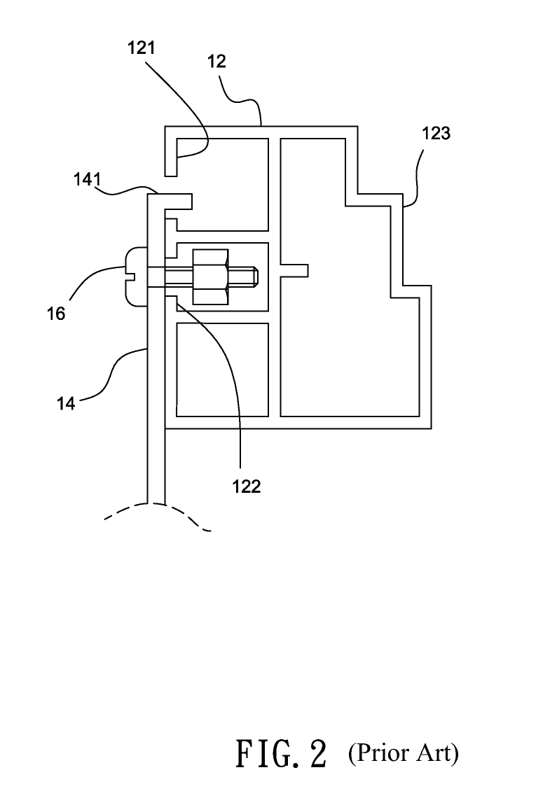

FIG. 3 is a schematic diagram of a frame structure of a concentrator type solar cell module according to the present invention;

FIG. 4 is a schematic diagram of a frame structure of a concentrator type solar cell module connecting to a sideboard according to the present invention;

FIG. 5 is a schematic diagram of a frame structure of a concentrator type solar cell module connecting to a sideboard and a concentrator lens array according to the present invention; and

FIG. 6 is a schematic diagram of a concentrator type solar cell module according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

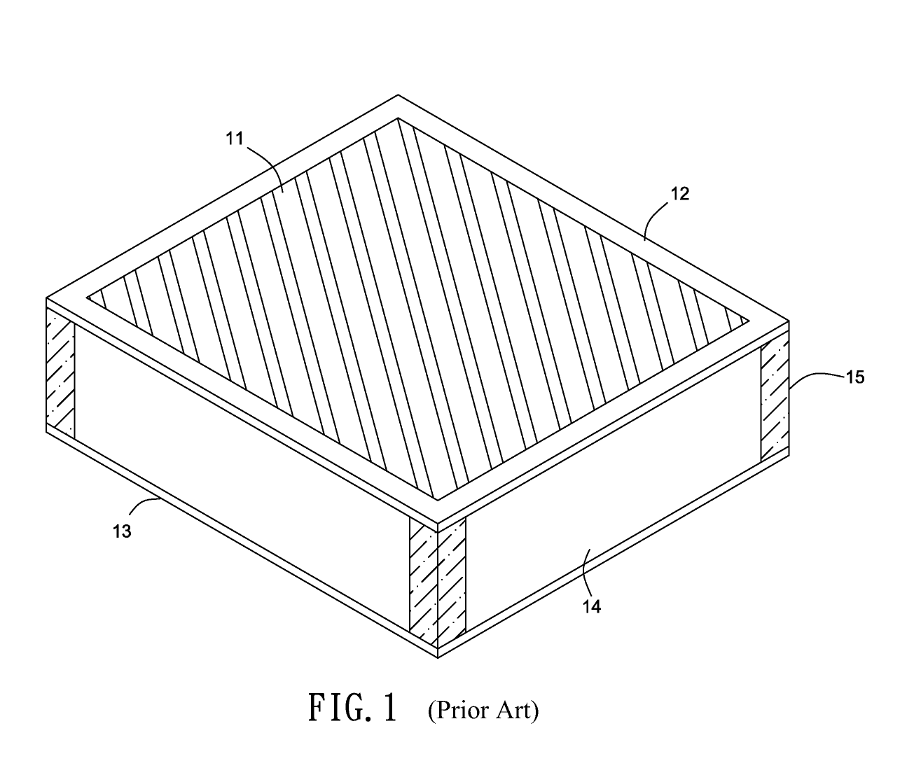

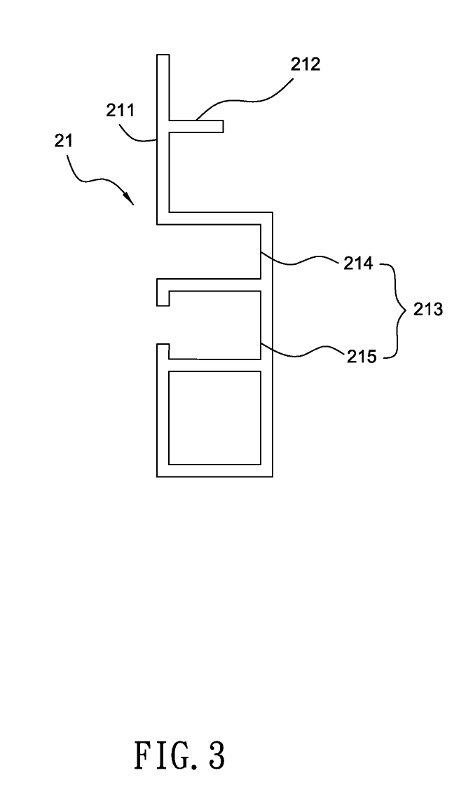

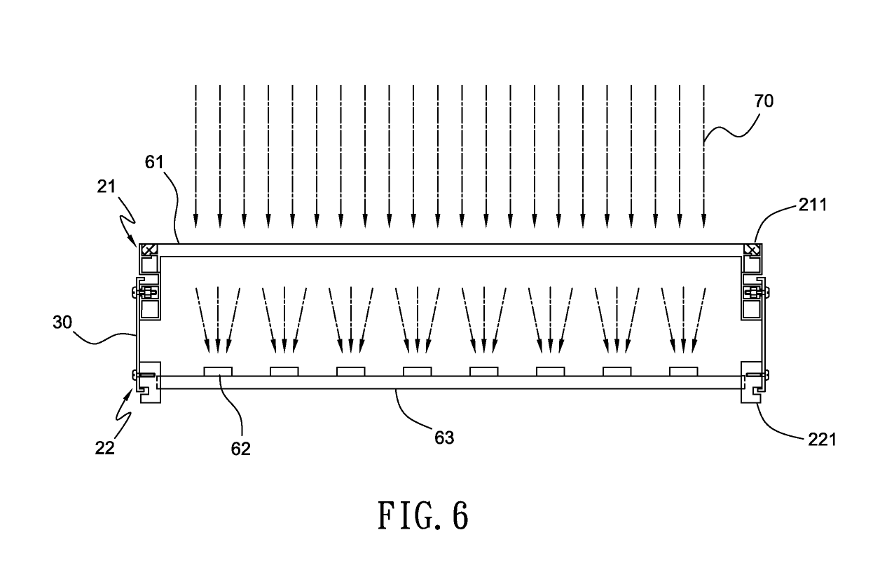

Refer to FIG. 3 for a schematic diagram of a frame structure of a concentrator type solar cell module according to the present invention, and FIG. 6 for a schematic diagram of a concentrator type solar cell module according to the present invention. As shown in FIGS. 3 and 6, a frame structure of the concentrator type solar cell module includes two frames (an upper frame 21 and a lower frame 22), four sideboards 30 (refer to FIG. 1 at the same time), etc.

The upper frame 21 and the lower frame 22 are arranged parallel to each other in an upper and lower configuration, and both are composed of four frame edges 211 and 221 to form a rectangle-shaped body. The upper and lower sides of each sideboards 30 are fixed into the corresponding frame edges 211 and 221 of the upper frame 21 and lower frame 22 respectively, thus forming and enclosing an inner space for the disposition and installation of solar cell units 62; meanwhile, the upper frame 21 and lower frame 22 are used to carry and support the concentrator lens array 61 and the heat dissipation module 63 with solar cell units 62 disposed thereon.

In the structure mentioned above, the concentrator lens array 61 can be a Fresnel lens array, made of material of superior optical characteristics, such as light transmission resin of PPMA, PC, or PE, and its structure is a saw-tooth mirror on its lower side having outward incrementing angles, and its texture is designed and created by utilizing light interference, light diffraction, and light receiving angles. In an ordinary design, its focal length is 1 mm˜100 cm, with a light concentration ratio of 2×˜1000×. The solar cell unit 62 can be an III-V Semiconductor solar cell, and it is arranged corresponding to the concentrator lens array 61, so as to absorb the sunlight 70 concentrated and focused through the concentrator lens array 61, and then converts the sunlight 70 thus absorbed into electricity for outputting it to the equipment as required. Compared with an ordinary silicon solar cell, the III-V Semiconductor solar cell is able to absorb sunlight of wider spectrum, thus its photo-electric conversion efficiency can be raised significantly.

Moreover, the heat dissipation module 63 is designed to have superior heat dissipation function and solar cell unit 62 carrying and supporting capabilities, and it can be made of materials of superior heat dissipation as selected from a group consisting of: Ag, Cu, Al, Ni, Au, and the alloys thereof. Therefore, the high temperature generated by the solar cell unit 62 through absorbing the concentrated sunlight as focused by the concentrator lens array 61 can be dissipated into the ambient air, through the heat dissipation module 63 located at the bottom of the solar cell units 62, such that the solar cell units 62 may operate in a suitable temperature, thus prolonging its service life.

Subsequently, refer to FIG. 3. As shown in FIG. 3, the frame edge 211 of the upper frame 21 includes a carrier portion 212 and a connection and fixing portion 213, such that the carrier portion 212 is formed into a step-shaped structure so as to match the edge of the concentrator lens array 61. Of course, in case that the design of edges of the concentrator lens array 61 is changed, or different type of concentrator lens array 61 is utilized, then the shape of the carrier portion 212 can be changed accordingly, since it is mainly used to carry the concentrator lens array 61. The connection and fixing portion 213 includes a positioning slot 214 and a fixing slot 215, used for positioning and fixing sideboard 30. The designs of the carrier portion 212 and the connection and fixing portion 213 are different from those of the prior art, such that it is in a vertical and stack-up configuration, so as to reduce its top area to the minimum.

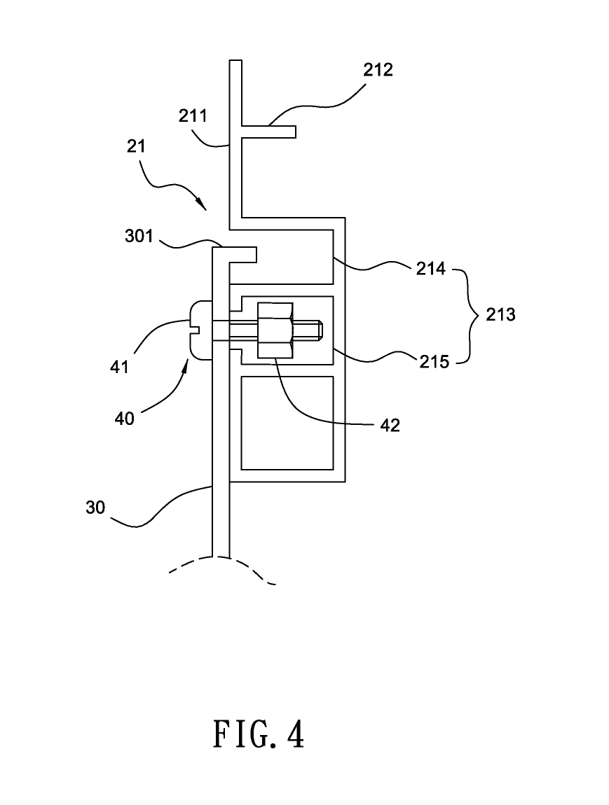

Refer to FIG. 4 for a schematic diagram of a frame structure of a concentrator type solar cell module connecting to a sideboard according to the present invention. The positioning position 301 extended and bent at an edge of a sideboard 30 is engaged and positioned into a positioning slot 214 of frame edge 211, so that the sideboard 30 is pressed tightly and fixed to the frame edge 211 of the upper frame 21, and a fixing element 40 is used to penetrate the frame edge 211 of the upper frame 21 and sideboard 30, so as to fix them together tightly. As shown in FIG. 4, the fixing element 40 can be of a screw 41 and nut 42 type, and the nut 42 is placed in the fixing slot 215, such that the screw 41 penetrates the sideboard 30 and gets in touch with the nut 42, and fixes the sideboard 30 into such a position. Of course, the present invention is not limited to the above mentioned fixing element 40, other types of the fixing element 40 such as a rivet, pin, fastener can also be utilized.

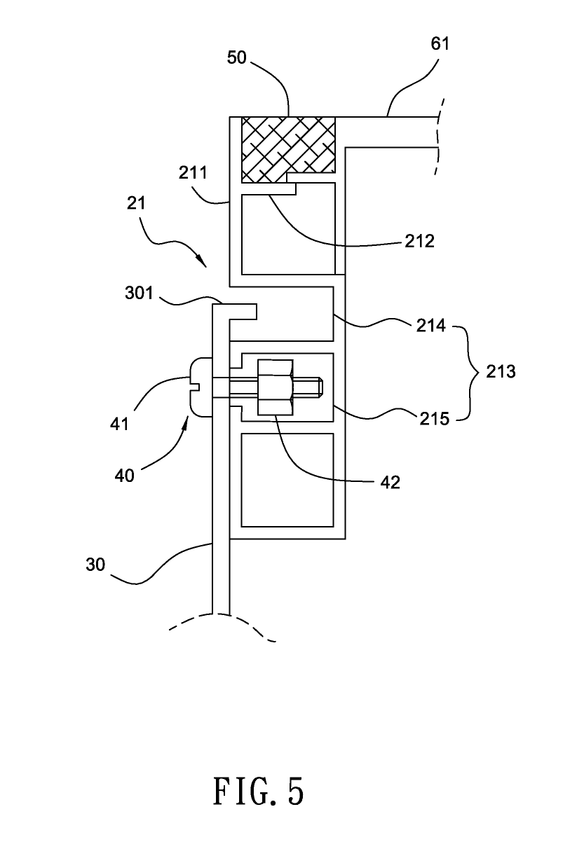

Then, refer to FIG. 5 for a schematic diagram of a frame structure of a concentrator type solar cell module connecting to a sideboard and a concentrator lens array according to the present invention.

As shown in FIG. 5, the concentrator lens array 61 can be disposed on the carrier portion 212 of the frame edge 211 of the upper frame 21, then in cooperation with the buffer adhesive such as silicone 50 filled in the gap between the carrier portion 212 and the concentrator lens array 61, hereby achieving the adhering and fixing of the concentrator lens array 61 in a proper position. Therefore, on the whole, the entire frame edge 211 is a hollow structure, such that not only material is saved, but its weight is also reduced.

Finally, refer to FIG. 6 for a schematic diagram of a concentrator type solar cell module according to the present invention. As shown in FIG. 6, the overall thickness of frame edge 211 is reduced. In other words, the proportion of the entire upper surface area of concentrator lens array 61 is increased. According to a formula of calculating the conversion efficiency, the conversion efficiency is a ratio of the output power to the input power, while the input power is a product of the sunlight intensity times the light receiving area, such that in this way, though actually, the area of concentrator lens array 61 is not changed, yet due to the reduction of area of frame edge 211, the proportion of the area occupied by concentrator lens array 61 (the effective light receiving area) is increased. Therefore, the overall photo-electric conversion efficiency of the solar cell module is increased.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A frame structure of a concentrator type solar cell module, having a rectangular body formed by four frame edges, and each of said frame edges being connected and fixed to a sideboard, and used to carry a concentrator lens array; wherein each of said frame edges is provided with a carrier portion and a connection and fixing portion, said connection and fixing portion is used to connect and fix to said sideboard, and said carrier portion is used for placing a concentrator lens array, said carrier portion and said connection and fixing portion are placed in a vertical and stack-up arrangement, so as to reduce a thickness of said frame edge.

2. The frame structure of a concentrator type solar cell module as claimed in claim 1, wherein a plurality of fixing elements are utilized to penetrate said sideboards and said frame edges, so as to make said sideboards and said frame edges pressed tightly to each other.

3. The frame structure of a concentrator type solar cell module as claimed in claim 2, wherein said fixing elements are fixing screws, used to screw and fix said sideboards to said frame edges.

4. The frame structure of a concentrator type solar cell module as claimed in claim 2, wherein said connection and fixing portion of said frame edge includes a fixing slot, used to install said fixing element.

5. The frame structure of a concentrator type solar cell module as claimed in claim 4, wherein said connection and fixing portion of said frame edge includes a positioning slot, and said sideboard is provided with an extended and bent positioning portion at an edge thereof and corresponding to said positioning slot, so as to be engaged and positioned in said positioning slot to fix said sideboard.

6. The frame structure of a concentrator type solar cell module as claimed in claim 1, wherein, upon installing said concentrator lens array on said carrier portion of said frame edge, silicone is filled into a gap between said carrier portion and said concentrator lens array, so as to adhere and fix said concentrator lens array on said carrier portion.

7. The frame structure of a concentrator type solar cell module as claimed in claim 1, wherein said frame edge is a hollow structure, so as to reduce a weight thereof.
